(19) United States
(12) Patent Application Publication
(10) Pub. No.: US 2026/0337758 A1
(43) Pub. Date: Oct. 29, 2026

(54) NANOTWINNED SILVER MATERIAL AND PREPARATION METHOD THEREOF

(71) Applicant: HARBIN INSTITUTE OF TECHNOLOGY, SHENZHEN, Shenzhen (CN)

(72) Inventors: Hongjun JI, Shenzhen (CN); Dashi LU, Shenzhen (CN); Wenwu ZHANG, Shenzhen (CN); Hao PAN, Shenzhen (CN); Xiuqi WANG, Shenzhen (CN); Mingyu LI, Shenzhen (CN)

(21) Appl. No.: 19/107,851

(22) PCT Filed: Mar. 20, 2024
(86) PCT No.: PCT/CN2024/082575

§ 371 Date: Feb. 28, 2025

(30) Foreign Application Priority Data
Jun. 26, 2023 (CN) 202310758841.8

(51) Int. Cl. C23C 14/35; B82Y 30/00; B82Y 40/00; C23C 14/02; C23C 14/16; C23C 14/34

(52) U.S. Cl. CPC C23C 14/35; C23C 14/021; C23C 14/16; C23C 14/3414; B82Y 30/00; B82Y 40/00

(57) ABSTRACT

Provided are a nanotwinned silver material and a preparation method thereof. The preparation method includes: step S1, cleaning and drying a substrate; and step S2, selecting a silver target as a target, placing the substrate and the target in a magnetron sputtering equipment, vacuuming, and conducting a deposition through direct current (DC) magnetron sputtering on the substrate by applying a negative bias voltage to the substrate, where the negative bias voltage for the substrate is in a range of −200 volts to −50 volts, the substrate is at a temperature of 25 °C to 50 °C, a flow for argon is in a range of 30 sccm to 50 sccm, a vacuum degree of a sputtering chamber is in a range of 0.3 Pa to 1.0 Pa, and the deposition is conducted for 15 minutes to 90 minutes.

### CROSS REFERENCE TO RELATED APPLICATION

The present application is a national stage application of International Patent Application No. PCT/CN2024/082575, filed on Mar. 20, 2024, which claims priority to Chinese Patent Application No. 202310758841.8 filed with the China National Intellectual Property Administration (CNIPA) on Jun. 26, 2023. The disclosure of the two applications is incorporated herein by reference in its entirety.

### TECHNICAL FIELD

The present disclosure relates to the field of advanced metal material preparation technology, in particular to a nanotwinned silver material and a preparation method thereof.

### BACKGROUND

With the gradual development of packaging technology towards high density and reliability, packaging technology requires interconnect materials to have a series of excellent properties such as high strength, excellent electrical conductivity and thermal conductivity, thermal stability, resistance to electromigration, and ability to serve at high temperatures. As a metal with excellent electrical conductivity, thermal conductivity, and oxidation resistance, silver is one of the key materials for achieving electrical interconnection in electronic circuit manufacturing. However, the inherent low strength of silver and its poor electromigration resistance during service as an interconnect material severely limit its use in the field of electronic packaging and interconnection.

### SUMMARY

In view of the above technical problems, the present disclosure provides a nanotwinned silver material and a preparation method thereof. The nanotwinned silver material shows excellent properties such as high strength, electromigration resistance, high thermal stability, and high thermal and electrical conductivity.

The present disclosure provides the following technical solutions:

The present disclosure provides a method for preparing a nanotwinned silver material, including the following steps:
step S1, cleaning and drying a substrate; and
step S2, selecting a silver target as a target, placing the substrate and the target in a magnetron sputtering equipment, vacuuming, and conducting a deposition through direct current (DC) magnetron sputtering on the substrate by applying a negative bias voltage to the substrate, where
the negative bias voltage for the substrate is in a range of −200 V to −50 V, the substrate is at a temperature of 25 °C to 50 °C, a flow for argon is in a range of 30 sccm to 50 sccm, a vacuum degree of a sputtering chamber is a range of 0.3 Pa to 1.0 Pa, and the deposition is conducted for 15 min to 90 min.

The nanotwinned silver material has high density, and has higher strength and excellent electromigration resistance without deteriorating the electrical and thermal conductivity of the silver material. Due to low grain boundary energy of a coherent nanotwin boundary that is only about 10% of that of a large angle grain boundary, nanotwins in the material can further effectively improve the thermal stability of the material at high temperature. This high-density nanotwinned silver used as an interconnect material is expected to solve the problems of low shear strength and poor electromigration resistance of a silver interconnecting layer, improving the service temperature and reliability of bonding joints.

In some embodiments, in step S2, the deposition is conducted at a power of 100 W to 300 W.

In some embodiments, the target is the silver target with a silver content of 99.999%.

In some embodiments, in step S2, a distance between the substrate and the target is in a range of 10 cm to 20 cm.

In some embodiments, the substrate is one selected from the group consisting of a silicon substrate and a copper substrate.

In some embodiments, the substrate has a thickness of 200 μm to 500 μm.

In some embodiments, step S1 includes cleaning a polished substrate with an acid solution and deionized water in sequence, spin-drying surface water of a resulting substrate, and then drying.

The present disclosure further provides a nanotwinned silver material prepared by the method for preparing the nanotwinned silver material.

In some embodiments, an internal microstructure of the nanotwinned silver material comprises (consists of) columnar crystals grown in a deposition direction with a width of 200 nm to 1,000 nm, nanotwin lamellae perpendicular to the deposition direction are provided inside the columnar crystals, and the nanotwin lamellae each have an average thickness of 10 nm to 100 nm.

In some embodiments, there is (111) preferred orientation on surfaces of the columnar crystals.

In some embodiments, the nanotwinned silver material has a thickness of 2 μm to 50 μm.

Compared with the prior art, some embodiments of the present disclosure have the following beneficial effects:
First, the nanotwinned silver material prepared using present disclosure features high-density nanotwins with a twin boundary fraction exceeding 90%. While maintaining excellent electrical conductivity and thermal conductivity, the material demonstrates significantly enhanced hardness, electromigration resistance, and thermal stability; the nanotwinned silver material shows excellent comprehensive properties, which can solve the existing problems of low strength and poor electromigration resistance of silver materials and can be used as a bonding material in the fields of power device packaging, advanced packaging, and micro-electro-mechanical system (MEMS) packaging.
Second, the nanotwinned silver material prepared by magnetron sputtering technology has the advantages of uniform controllable thickness and microstructure, and strong adhesive strength; moreover, the physical vapor deposition technology is compatible with the microelectronic manufacturing process.

### BRIEF DESCRIPTION OF THE DRAWINGS

FIG. 1 shows a focused ion beam (FIB) image of the cross section of a nanotwinned silver material deposited on a silicon substrate in Example 1 of the present disclosure;

FIG. 2 shows a transmission electron microscope (TEM) image of a nanotwinned silver material deposited on a silicon substrate in Example 1 of the present disclosure, depicting high-density nanotwin lamellae perpendicular to a deposition direction, where the arrow indicates the deposition direction of the material;

FIG. 3 shows an FIB image of a cross section of a silver material deposited on a silicon substrate in Comparative Example 1 of the present disclosure;

FIG. 4 shows an FIB image of a nanotwinned silver material deposited on a silicon substrate in Example 3 of the present disclosure; and

FIG. 5 shows an FIB image of a nanotwinned silver material deposited on a silicon substrate in Example 4 of the present disclosure.

### DETAILED DESCRIPTION OF THE EMBODIMENTS

The preferred examples of the present disclosure will be further described in detail below.

### Example 1

A high-density nanotwinned silver material was prepared on a <111>-monocrystalline silicon substrates at a bias voltage by DC magnetron sputtering technology. In the example, a method for preparing the high-density nanotwinned silver material by magnetron sputtering technology was performed as follows:
Step S1, a 2-inch <111> monocrystalline silicon substrate after chemical mechanical polishing (CMP) was cleaned with a solution of hydrofluoric acid and water at a ratio of 1:50 (mass ratio) to remove a surface oxide film, and then cleaned with deionized water; and surface water was spin-dried in a spin dryer and the silicon substrate was dried for later use.
Step S2, the silicon substrate from which the surface oxide film has been removed and a 99.999% silver target were placed in a magnetron sputtering workbench, and a distance between the silicon substrate and the silver target was adjusted to 15 cm.
Step S3, after vacuuming, process parameters for sputtering deposition were set as follows: the bias voltage of −100 V was applied to the silicon substrate, a power was 250 W, the silicon substrate was at a temperature of 25 °C, a flow for argon was 40 sccm, and a vacuum degree of a sputtering chamber was 0.5 Pa; then, the sputtering deposition was conducted on the silicon substrate.
Step S4, step S3 was held for 20 min to obtain the high-density nanotwinned silver material with a thickness of about 3 μm.

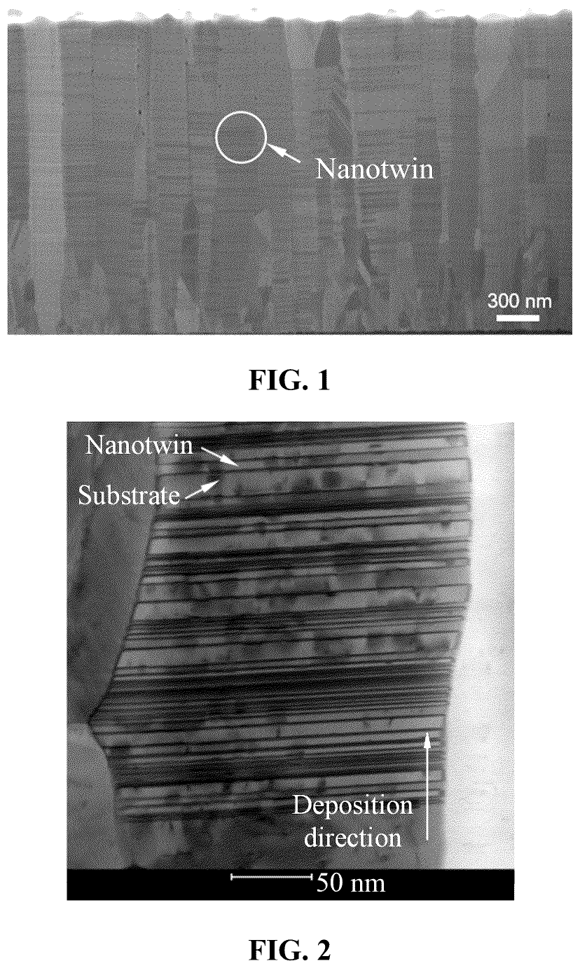

FIG. 1 shows an FIB image of the cross section of the nanotwinned silver material deposited on the silicon substrate in Example 1 of the present disclosure. It can be seen from the figure that almost all the crystal grains in the columnar crystals of the material contain high-density nanotwins, and the crystal grains with high-density nanotwins account for about 100%. FIG. 2 shows a TEM image of the nanotwinned silver material deposited on the silicon substrate, where nanotwins can be observed clearly.

### Example 2

A high-density nanotwinned silver material was prepared on a polycrystalline copper substrate at a bias voltage by DC magnetron sputtering technology. In the example, a method for preparing the high-density nanotwinned silver material by magnetron sputtering technology was performed as follows:
Step S1, the polycrystalline copper substrate after CMP was cleaned with a 5% (mass percentage) citric acid aqueous solution and then cleaned with deionized water; and surface water was spin-dried in a spin dryer and the polycrystalline copper substrate was dried for later use.
Step S2, the polycrystalline copper substrate from which a surface oxide film has been removed and a 99.999% silver target were placed in a magnetron sputtering workbench, and a distance between the polycrystalline copper substrate and the silver target was adjusted to 20 cm.
Step S3, after vacuuming, process parameters for sputtering deposition were set as follows: the bias voltage of −100 V was applied to the polycrystalline copper substrate, a power was 300 W, the polycrystalline copper substrate was at a temperature of 25 °C, a flow for argon was 50 sccm, and a vacuum degree of a sputtering chamber was 0.5 Pa; then, the sputtering deposition was conducted on the polycrystalline copper substrate.
Step S4, step S3 was held for 30 min to obtain the high-density nanotwinned silver material with a thickness of about 10 μm.

### Comparative Example 1

The comparative example was performed as follows:
Step S1, a 2-inch <111> monocrystalline silicon substrate after chemical mechanical polishing (CMP) was cleaned with a solution of hydrofluoric acid and water at a ratio of less than 1:50 to remove a surface oxide film; after that, and then cleaned with deionized water; and surface water was spin-dried in a spin dryer and the silicon substrate was dried for later use.
Step S2, the silicon substrate from which the surface oxide film has been removed and a 99.999% silver target were placed in a magnetron sputtering workbench, and a distance between the silicon substrate and the silver target was adjusted to 15 cm.
Step S3, after vacuuming, process parameters for sputtering deposition were set as follows: no bias voltage was applied to the silicon substrate, a power was 250 W, the silicon substrate was at a temperature of 25 °C, a flow for argon was 40 sccm, and a vacuum degree of a sputtering chamber was 0.5 Pa; then, the sputtering deposition was conducted on the silicon substrate.
Step S4, step S3 was held for 20 min to obtain a nano-silver material with a thickness of about 3 μm.

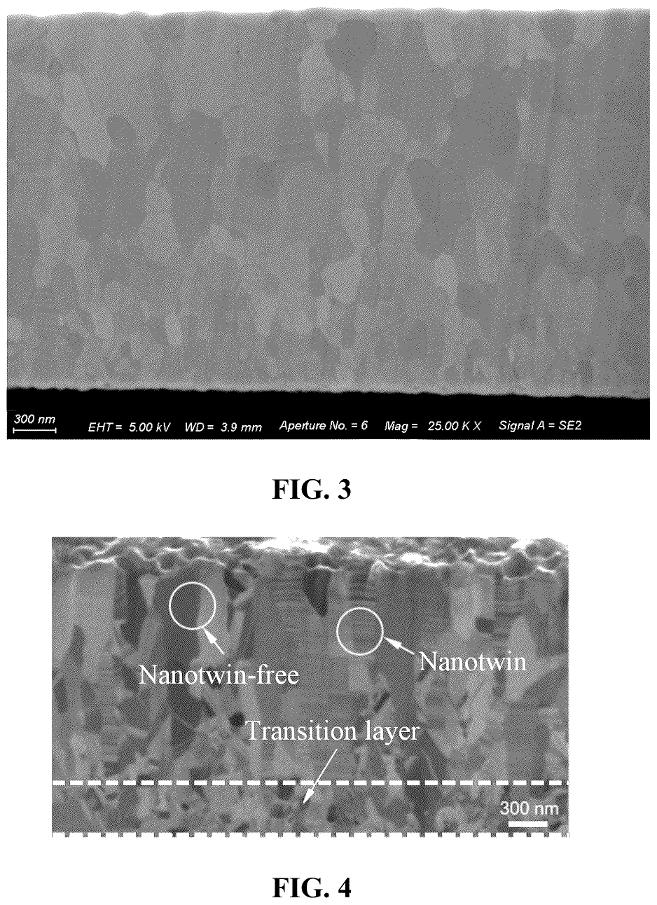

FIG. 3 shows an FIB image of a cross section of a nanotwinned silver material deposited on the silicon substrate in Comparative Example 1. From the microstructure, it can be found that without applying a negative bias voltage, the bottom of a deposited material is an equiaxed crystal transition layer, only a few crystal grains have nanotwins, and no high-density nanotwinned material is obtained.

### Example 3

A high-density nanotwinned silver material was prepared on a <111> monocrystalline silicon substrates at a bias voltage by DC magnetron sputtering technology. In the example, a method for preparing the high-density nanotwinned silver material by magnetron sputtering technology was performed as follows:
Step S1, a 2-inch <111> monocrystalline silicon substrate after CMP was cleaned with a solution of hydrofluoric acid and water at a ratio of 1:50 (mass ratio) to remove a surface oxide film; and then cleaned with deionized water; and surface water was spin-dried in a spin dryer and the silicon substrate was dried for later use.
Step S2, the silicon substrate from which the surface oxide film has been removed and a 99.999% silver target were placed in a magnetron sputtering workbench, and a distance between the silicon substrate and the silver target was adjusted to 15 cm.
Step S3, after vacuuming, process parameters for sputtering deposition were set as follows: the bias voltage of −50 V was applied to the silicon substrate, a power was 250 W, the silicon substrate was at a temperature of 25 °C, a flow for argon was 40 sccm, and a vacuum degree of a sputtering chamber was 0.5 Pa; then, the sputtering deposition was conducted on the silicon substrate.
Step S4, step S3 was held for 20 min to obtain the high-density nanotwinned silver material with a thickness of about 3 μm.

FIG. 4 shows an FIB image of the nanotwinned silver material deposited on the silicon substrate at a substrate bias voltage of −50 V in Example 4. It can be seen from the figure that there is an equiaxed grain transition layer at the bottom of a material obtained under this condition, and the volume fraction of crystal grains with high-density nanotwins accounts for about 50%.

### Example 4

A high-density nanotwinned silver material was prepared on a <111> monocrystalline silicon substrates at a bias voltage by DC magnetron sputtering technology. In the example, a method for preparing the high-density nanotwinned silver material by magnetron sputtering technology was performed as follows:
Step S1, a 2-inch <111> monocrystalline silicon substrate after CMP was cleaned with a solution of hydrofluoric acid and water at a ratio of 1:50 (mass ratio) to remove a surface oxide film, and then cleaned with deionized water; and surface water was spin-dried in a spin dryer and the silicon substrate was dried for later use.
Step S2, the silicon substrate from which the surface oxide film has been removed and a 99.999% silver target were placed in a magnetron sputtering workbench, and a distance between the silicon substrate and the silver target was adjusted to 15 cm.
Step S3, after vacuuming, process parameters for sputtering deposition were set as follows: the bias voltage of −200 V was applied to the silicon substrate, a power was 250 W, the silicon substrate was at a temperature of 25 °C, a flow for argon was 40 sccm, and a vacuum degree of a sputtering chamber was 0.5 Pa; then, the sputtering deposition was conducted on the silicon substrate.
Step S4, step S3 was held for 20 min to obtain the high-density nanotwinned silver material with a thickness of about 3 μm.

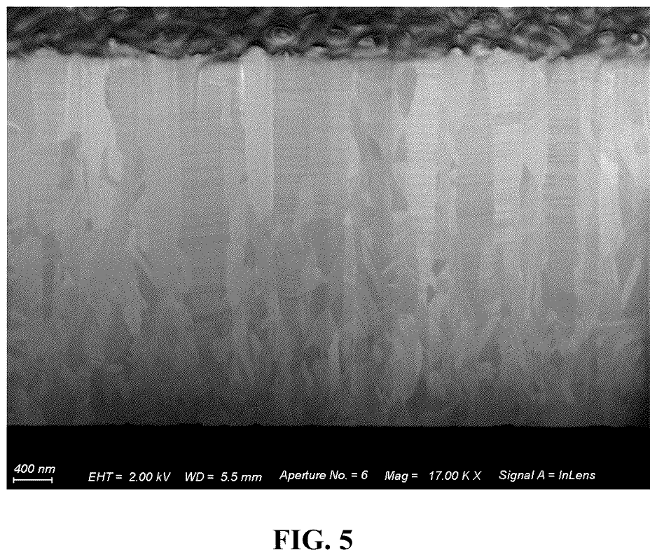

FIG. 5 shows an FIB image of the nanotwinned silver material deposited on the silicon substrate at a substrate bias voltage of −200 V in Example 4. It can be seen from the figure that the high-density nanotwinned silver material can also be obtained under this condition.

Using a nano-hardness tester, the hardness tests were conducted on magnetron sputtered silver (Ag) materials of Examples 1 to 4 and Comparative Example 1. The results are shown in Table 1 below. It can be seen that the hardness of the Ag material with low twin density in Comparative Example 1 is 0.88 GPa, and that of the Ag material with high density twins (90%-Nt) in Example 1 is 1.95 GPa, which is 2.21 times that of the Ag material in Comparative Example 1.

TABLE 1
The nano-hardness test results of examples and comparative example

| | | | | | Comparative |
|---|---|---|---|---|---|
| Material | Example 1 | Example 2 | Example 3 | Example 4 | Example 1 |
| Hardness/ | 1.95 | 1.86 | 1.43 | 1.69 | 0.88 |
| GPa | | | | | |

The magnetron sputtered Ag materials of Examples 1 to 4 and Comparative Example 1 were held at different temperatures for 1 h to test their thermal stability. The critical temperature at which the material began detwinning and crystal grains grew was determined to evaluate the thermal stability of the materials. The critical temperatures at which detwinning occurs in the materials are shown in Table 2. Compared with the 200 °C of the material of Comparative Example 1, the destabilization temperatures of the high-density twinned Ag materials of the examples are increased to 350 °C.

TABLE 2
The thermal stability test results of examples and comparative example

| | | | | | Comparative |
|---|---|---|---|---|---|
| Material | Example 1 | Example 2 | Example 3 | Example 4 | Example 1 |
| Destabil- | 350 | 350 | 300 | 300 | 200 |
| ization | | | | | |
| temper- | | | | | |
| ature/ | | | | | |
| °C | | | | | |

The present disclosure is described in further detail above with reference to the specific and preferred embodiments, but the description should not be construed as a limitation to the specific embodiments of the present disclosure. It will be apparent to those skilled in the art that several simple deductions or substitutions may be made without departing from the spirit of the present disclosure, and all such modifications or substitutions are intended to fall within the scope of the present disclosure.

What is claimed is:

1. A method for preparing a nanotwinned silver material, comprising:
step S1, cleaning and drying a substrate; and
step S2, selecting a silver target as a target, placing the substrate and the target in a magnetron sputtering equipment, vacuuming, and conducting a deposition through direct current (DC) magnetron sputtering on the substrate by applying a negative bias voltage to the substrate, wherein
the negative bias voltage for the substrate is in a range of −200 volts to −50 volts, the substrate is at a temperature of 25 °C to 50 °C, a flow for argon is in a range of 30 sccm (standard cubic centimeters per minute) to 50 sccm, a vacuum degree of a sputtering chamber is in a range of 0.3 Pa to 1.0 Pa, and the deposition is conducted for 15 minutes to 90 minutes.

2. The method for preparing the nanotwinned silver material of claim 1, wherein in step S2, the deposition is conducted at a power of 100 watts to 300 watts.

3. The method for preparing the nanotwinned silver material of claim 2, wherein the target is the silver target with a silver content of 99.999%.

4. The method for preparing the nanotwinned silver material of claim 3, wherein in step S2, a distance between the substrate and the target is in a range of 10 centimeters to 20 centimeters.

5. The method for preparing the nanotwinned silver material of claim 1, wherein the substrate is one selected from the group consisting of a silicon substrate and a copper substrate.

6. The method for preparing the nanotwinned silver material of claim 5, wherein the substrate has a thickness of 200 micrometers to 500 micrometers.

7. The method for preparing the nanotwinned silver material of claim 1, wherein step S1 comprises cleaning a polished substrate with an acid solution and deionized water in sequence, spin-drying surface water of a resulting substrate, and then drying.

8. A nanotwinned silver material prepared by the method for preparing the nanotwinned silver material of claim 1.

9. The nanotwinned silver material of claim 8, wherein an internal microstructure of the nanotwinned silver material comprises columnar crystals grown in a deposition direction with a width of 200 nanometers to 1,000 nanometers, nanotwin lamellae perpendicular to the deposition direction are provided inside the columnar crystals, and the nanotwin lamellae each have an average thickness of 10 nanometers to 100 nanometers.

10. The nanotwinned silver material of claim 8, wherein there is (111) preferred orientation on surfaces of the columnar crystals, and the nanotwinned silver material has a thickness of 2 micrometers to 50 micrometers.

11. The nanotwinned silver material of claim 8, wherein in step S2, the deposition is conducted at a power of 100 watts to 300 watts.

12. The nanotwinned silver material of claim 11, wherein the target is the silver target with a silver content of 99.999%.

13. The nanotwinned silver material of claim 12, wherein in step S2, a distance between the substrate and the target is in a range of 10 centimeters to 20 centimeters.

14. The nanotwinned silver material of claim 8, wherein the substrate is one selected from the group consisting of a silicon substrate and a copper substrate.

15. The nanotwinned silver material of claim 14, wherein the substrate has a thickness of 200 micrometers to 500 micrometers.

16. The nanotwinned silver material of claim 8, wherein step S1 comprises cleaning a polished substrate with an acid solution and deionized water in sequence, spin-drying surface water of a resulting substrate, and then drying.
